(19) United States
(12) Patent Application Publication
(10) Pub. No.: US 2025/0176365 A1
(43) Pub. Date: May 29, 2025

(54) DISPLAY DEVICE AND METHOD OF MANUFACTURING DISPLAY DEVICE

(71) Applicant: Samsung Display Co., LTD., Yongin-si (KR)

(72) Inventor: Hyun Eok SHIN, Yongin-si (KR)

(73) Assignee: Samsung Display Co., LTD., Yongin-si (KR)

(21) Appl. No.: 18/908,256

(22) Filed: Oct. 7, 2024

(30) Foreign Application Priority Data
Nov. 24, 2023 (KR) 10-2023-0165749

(51) Int. Cl. H10K 59/122; H10K 59/12

(52) U.S. Cl. CPC H10K 59/122; H10K 59/1201

(57) ABSTRACT

A display device includes a partition wall disposed on a base layer, and a light emitting unit disposed adjacent to the partition wall. The partition wall includes a first partition wall layer, a second partition wall layer disposed on the first partition wall layer, a first protruding layer disposed between the first partition wall layer and the second partition wall layer, and a second protruding layer disposed on the second partition layer. The first protruding layer protrudes over the first partition wall layer, and the second protruding layer protrudes over the second partition wall layer.

### CROSS-REFERENCE TO RELATED APPLICATION(S)

This application claims priority to and benefits of Korean Patent Application No. 10-2023-0165749 under 35 U.S.C. § 119, filed on Nov. 24, 2023, in the Korean Intellectual Property Office (KIPO), the contents of which are incorporated herein by reference.

### BACKGROUND

### 1. Technical Field

The disclosure relates to a display device and a method of manufacturing the display device.

### 2. Description of the Related Art

As information technology develops, the importance of a display device, which is a connection medium between a user and information, is emerging. Accordingly, research and development on the display device is continuously being conducted.

The display device may include a partition wall defining an area in which a light emitting unit is disposed, and a protective layer covering at least a portion of the partition wall. When a protective layer of the display device is not properly formed, a risk that an external impurity (for example, moisture) permeates into the display device may increase.

### SUMMARY

An aspect of the disclosure is to provide a display device and a method of manufacturing the display device having a protective structure capable of stably covering a partition wall while reducing a risk that an external impurity is to be permeated.

According to an embodiment of the disclosure, a display device may include a partition wall disposed on a base layer, and a light emitting unit disposed adjacent to the partition wall. The partition wall may include a first partition wall layer, a second partition wall layer disposed on the first partition wall layer, a first protruding layer disposed between the first partition wall layer and the second partition wall layer, and a second protruding layer disposed on the second partition layer. The first protruding layer may protrude over the first partition wall layer, and the second protruding layer may protrude over the second partition wall layer.

According to an embodiment, the first partition wall layer and the second partition wall layer may include a conductive metal.

According to an embodiment, the first partition wall layer and the second partition wall layer may include molybdenum (Mo).

According to an embodiment, the first partition wall layer may have a thickness in a range of about 2000 Å to about 4000 Å, and the second partition wall layer may have a thickness in a range of about 1000 Å to about 3000 Å.

According to an embodiment, the first partition wall layer and the second partition wall layer may have an inclined side surface.

According to an embodiment, the first protruding layer may include a first-first protruding layer disposed on the first partition wall layer, and a first-second protruding layer disposed on the first-first protruding layer, and the second protruding layer may include a second-first protruding layer disposed on the second partition wall layer, and a second-second protruding layer disposed on the second-first protruding layer.

According to an embodiment, the first-first protruding layer and the second-first protruding layer may include at least one of silicon nitride (SiNₓ), silicon oxide (SiOₓ), and silicon oxynitride (SiOₓN_{y}), and the first-second protruding layer and the second-second protruding layer may include at least one of titanium (Ti) and tantalum (Ta).

According to an embodiment, the first-second protruding layer and the second-second protruding layer may include at least one of silicon nitride (SiNₓ), silicon oxide (SiOₓ), and silicon oxynitride (SiOₓN_{y}), and the first-first protruding layer and the second-first protruding layer may include at least one of titanium (Ti) and tantalum (Ta).

According to an embodiment, the first-first protruding layer and the second-first protruding layer may have a thickness in a range of about 200 Å to about 500 Å, and the first-second protruding layer and the second-second protruding layer may have a thickness in a range of about 300 Å to about 1000 Å.

According to an embodiment, the first-second protruding layer and the second-second protruding layer may have a thickness in a range of about 200 Å to about 500 Å, and the first-first protruding layer and the second-first protruding layer may have a thickness in a range of about 300 Å to about 1000 Å.

According to an embodiment, the display device may further include a protective layer covering at least a portion of the partition wall. The protective layer may contact a side surface of the second partition wall layer, at least a portion of a lower surface of each of the first-first protruding layer and the second-first protruding layer, and an upper surface of each of the first-second protruding layer and the second-second protruding layer.

According to an embodiment, the display device may further include a first electrode and a second electrode disposed on the base layer. The light emitting unit may be disposed on the first electrode, the second electrode may be disposed on the light emitting unit, and the second electrode may contact a side surface of the first partition wall layer and may not contact a side surface of the second partition wall layer.

According to an embodiment of the disclosure, a method of manufacturing a display device may include forming a partition wall on a base layer, and forming a light emitting unit adjacent to the partition wall. The forming of the partition wall on the base layer may include depositing a first base partition wall layer, a first base protruding layer, a second base partition wall layer, and a second base protruding layer on the base layer, and etching the first base partition wall layer, the first base protruding layer, the second base partition wall layer, and the second base protruding layer. The etching of the first base partition wall layer, the first base protruding layer, the second base partition wall layer, and the second base protruding layer may include forming a first partition wall layer, forming a second partition wall layer on the first partition wall layer, forming a first protruding layer between the first partition wall layer and the second partition wall layer, and forming a second protruding layer on the second partition wall layer. The first protruding layer may protrude over the first partition wall layer, and the second protruding layer may protrude over the second partition wall layer.

According to an embodiment, the first partition wall layer and the second partition wall layer may include molybdenum (Mo).

According to an embodiment, the first base partition wall layer and the second base partition wall layer may be deposited through a sputtering process.

According to an embodiment, the first protruding layer may include a first-first protruding layer disposed on the first partition wall layer, and a first-second protruding layer disposed on the first-first protruding layer, and the second protruding layer may include a second-first protruding layer disposed on the second partition wall layer, and a second-second protruding layer disposed on the second-first protruding layer.

According to an embodiment, the first-first protruding layer and the second-first protruding layer may include at least one of silicon nitride (SiNₓ), silicon oxide (SiOₓ), and silicon oxynitride (SiOₓN_{y}), and may be deposited through a chemical vapor deposition (CVD) process, and the first-second protruding layer and the second-second protruding layer may include at least one of titanium (Ti) and tantalum (Ta).

According to an embodiment, the first-second protruding layer and the second-second protruding layer may include at least one of silicon nitride (SiNₓ), silicon oxide (SiOₓ), and silicon oxynitride (SiOₓN_{y}), and may be deposited through a chemical vapor deposition (CVD) process, and the first-first protruding layer and the second-first protruding layer may include at least one of titanium (Ti) and tantalum (Ta).

According to an embodiment, in the etching of the first base partition wall layer, the first base protruding layer, the second base partition wall layer, and the second base protruding layer, the first base partition wall layer, the first base protruding layer, the second base partition wall layer, and the second base protruding layer may be dry etched in batches, the first base partition wall layer may form a first intermediate partition wall layer, and the second base partition wall layer may form a second intermediate partition wall layer.

According to an embodiment, the first intermediate partition wall layer and the second intermediate partition wall layer may be further dry etched to form the first partition wall layer and the second partition wall layer, respectively.

According to an embodiment of the disclosure, a display device and a method of manufacturing a display device having a protective structure capable of stably covering a partition wall while reducing a risk that an external impurity is to be permeated may be provided.

### BRIEF DESCRIPTION OF THE DRAWINGS

The above and other features of the disclosure will become more apparent by describing in further detail embodiments thereof with reference to the accompanying drawings, in which:

FIG. 1 is a schematic plan view illustrating a display device according to an embodiment;

FIG. 2 is a schematic cross-sectional view illustrating a display device according to an embodiment;

FIG. 3 is a schematic cross-sectional view illustrating an embodiment of a light emitting element of FIG. 2;

FIG. 4 is a schematic cross-sectional view illustrating another embodiment of the light emitting element of FIG. 2;

FIG. 5 is a schematic block diagram illustrating an electrical connection structure for a light emitting element according to an embodiment;

FIG. 6 is a schematic flowchart illustrating a method of manufacturing a display device according to an embodiment;

FIGS. 7 to 13 are schematic cross-sectional views for each process step illustrating a method of manufacturing a display device according to an embodiment;

FIG. 14 is a schematic block diagram of a display system according to an embodiment; and

FIGS. 15 and 16 are schematic perspective views illustrating an application example of the display system of FIG. 14.

### DETAILED DESCRIPTION OF THE EMBODIMENT

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure. In the following description, the singular expressions include plural expressions unless the context clearly dictates otherwise.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure relates to a display device and a method of manufacturing the display device. Hereinafter, a display device and a method of manufacturing the display device according to an embodiment are described with reference to the accompanying drawings.

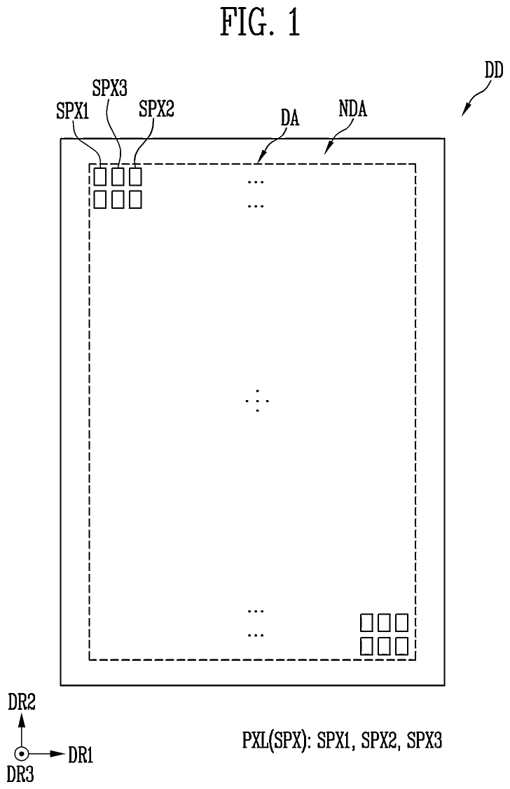

FIG. 1 is a schematic plan view illustrating a display device according to an embodiment.

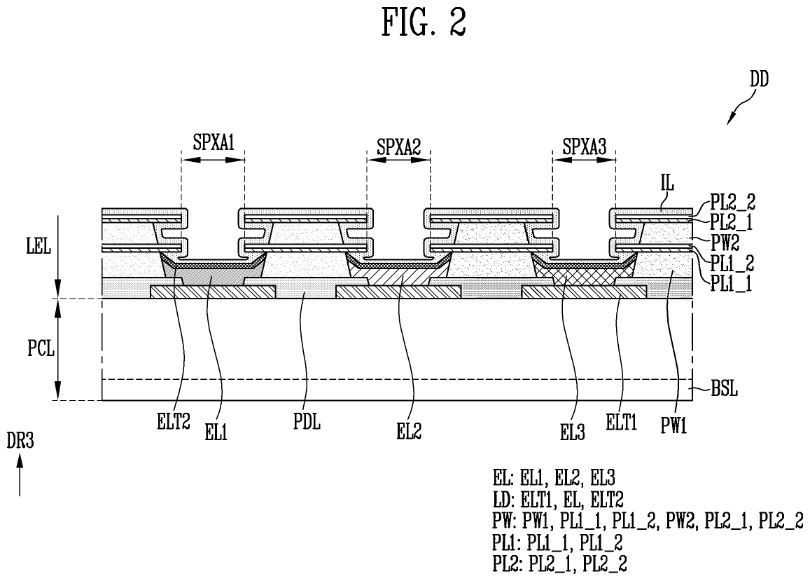

Referring to FIG. 1, the display device DD may be configured to emit light. The display device DD may include a light emitting element LD (refer to FIG. 2). According to an embodiment, the display device DD may be a device for displaying a moving image or a still image. The display device DD may be used as a display screen of various products such as not only a portable electronic device such as a mobile phone, a smart phone, a tablet personal computer (PC), a smart watch, a watch phone, a mobile communication terminal, an electronic notebook, an electronic book, a portable multimedia player (PMP), a navigation device, and an ultra mobile PC (UMPC), but also a television, a notebook computer, a monitor, a billboard, and Internet of things (IOT). However, an application field of the display device DD is not limited to a specific example.

The display device DD may be formed in a plane of a rectangular shape having a short side of a first direction DR1 and a long side of a second direction DR2 intersecting the first direction DR1 in a plan view. A corner where the short side of the first direction DR1 and the long side of the second direction DR2 meet may be formed to be rounded to have a curvature or may be formed in a right angle. A planar shape of the display device DD is not limited to a quadrangle, and may be formed in another polygon or may be formed in a round shape such as a circle or an ellipse. The display device may be formed to be flat, but the disclosure is not limited thereto. For example, the display device DD may include a curved portion formed at left and right ends and having a constant curvature or a varying curvature. The display device DD may be flexibly formed to be crooked, curved, bent, folded, or rolled.

In the disclosure, the first direction DR1 may be a row direction of a pixel PXL and may be a “horizontal” direction. The second direction DR2 may be a column direction of the pixel PXL. A third direction DR3 may be a display direction of the display device DD or a normal direction of a plane in which a base layer BSL is disposed.

The display device DD may include a display area DA and a non-display area NDA. The non-display area NDA may be an area other than the display area DA. The non-display area NDA may surround at least a portion of the display area DA in a plan view.

The display area DA may be an area where the pixel PXL is disposed. The non-display area NDA may be an area in which the pixel PXL is not disposed. A driving circuit unit, lines, and pads connected to the pixel PXL of the display area DA may be disposed in the non-display area NDA.

According to an embodiment, the pixel PXL (or sub-pixels SPX) may include a first sub-pixel SPX1, a second sub-pixel SPX2, and a third sub-pixel SPX3. At least one of the first sub-pixel SPX1, the second sub-pixel SPX2, and the third sub-pixel SPX3 may form one pixel unit PXU capable of emitting light of various colors. In FIG. 1, an embodiment in which each pixel PXL includes three sub-pixels SPX1, SPX2, and SPX3, for example, the first sub-pixel SPX1, the second sub-pixel SPX2, and the third sub-pixel SPX3 is illustrated, but the disclosure is not limited thereto.

According to an embodiment, the pixels PXL (or the sub-pixels SPX) may be arranged according to a stripe or a PENTILE™ arrangement structure or the like. However, the disclosure is not necessarily limited thereto.

The first sub-pixel SPX1 may emit first light, the second sub-pixel SPX2 may emit second light, and the third sub-pixel SPX3 may emit third light. The first light may be light of a red wavelength band, the second light may be light of a green wavelength band, and the third light may be light of a blue wavelength band. The red wavelength band may be a wavelength band in a range of about 600 nm to about 750 nm, the green wavelength band may be a wavelength band in a range of about 480 nm to about 560 nm, and the blue wavelength band may be a wavelength band in a range of about 370 nm to about 460 nm, but the disclosure is not limited thereto.

Each of the first sub-pixel SPX1, the second sub-pixel SPX2, and the third sub-pixel SPX3 may include an organic light emitting element (organic light emitting diode (OLED)) as a light emitting element emitting light.

Hereinafter, with reference to FIGS. 2 to 4, a display device DD according to an embodiment including an organic light emitting element is described.

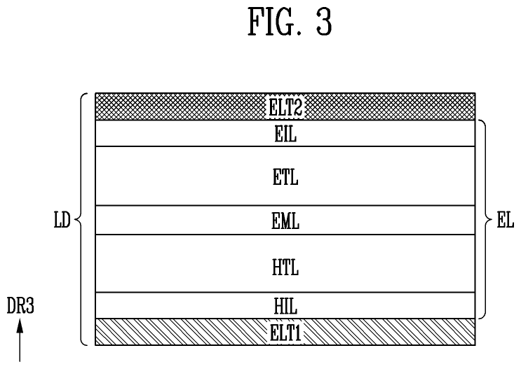

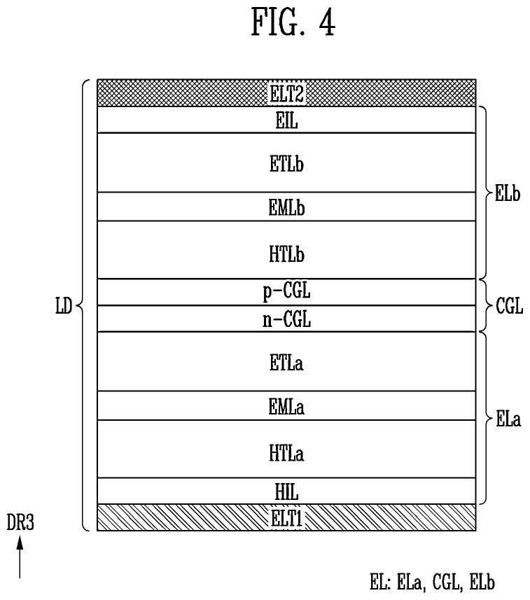

FIG. 2 is a schematic cross-sectional view illustrating a display device according to an embodiment. FIG. 3 is a schematic cross-sectional view illustrating an embodiment of the light emitting element of FIG. 2. FIG. 4 is a schematic cross-sectional view illustrating another embodiment of the light emitting element of FIG. 2.

Referring to FIG. 2, the display device DD may include a pixel circuit layer PCL and a light emitting element layer LEL.

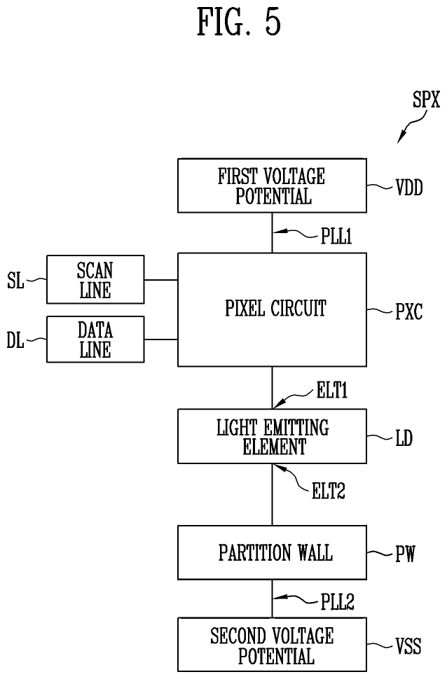

The pixel circuit layer PCL may be a layer including a pixel circuit PXC (refer to FIG. 5) for driving the light emitting elements LD. The pixel circuit layer PCL may include a base layer BSL, conductive layers for forming pixel circuits, and insulating layers disposed between the conductive layers.

According to an embodiment, the pixel circuit PXC may include circuit elements (for example, a driving transistor and the like) and may be electrically connected to the light emitting elements LD to provide an electrical signal for the light emitting elements LD to emit light.

The light emitting element layer LEL may be disposed on the pixel circuit layer PCL. According to an embodiment, the light emitting element layer LEL may include a pixel defining layer PDL, a partition wall PW, the light emitting element LD, and a protective layer IL.

The light emitting element LD may be disposed on the pixel circuit layer PCL or base layer BSL. According to an embodiment, the light emitting element LD may include a first electrode ELT1, a light emitting unit EL, and a second electrode ELT2. The first electrodes ELT1 may be disposed on a base layer BSL (or the pixel circuit layer PCL). The light emitting units EL may be disposed on the first electrodes ELT1. The second electrodes ELT2 may be disposed on the light emitting units EL.

According to an embodiment, the light emitting units EL may be disposed in an area defined by the pixel defining layer PDL and the partition wall PW (for example, a first sub-pixel area SPXA1, a second sub-pixel area SPXA2, or a third sub-pixel area SPXA3 of FIG. 2). Each of the light emitting units EL may be disposed between the partition walls PW. The light emitting unit EL may be disposed adjacent to the partition wall PW.

According to an embodiment, the sub-pixels SPX may include the light emitting unit EL respectively emitting light of different colors. For example, the light emitting unit EL may include a first light emitting unit EL1 for forming the first sub-pixel SPX1 emitting light of a first color, a second light emitting unit EL2 for forming the second sub-pixel SPX2 emitting light of a second color, and a third light emitting unit EL3 for forming the third sub-pixel SPX3 emitting light of a third color. However, the disclosure is not limited thereto. For example, each of the sub-pixels SPX may include a light emitting unit EL emitting a same color, and the display device DD may further include a color filter and may further include a wavelength conversion structure (for example, a quantum-dot) and the like.

A surface of the light emitting unit EL may be electrically connected to a surface of the first electrode ELT1, and another surface of the light emitting unit EL may be electrically connected to the second electrode ELT2.

The first electrode ELT1 may be an anode electrode for the light emitting unit EL, and the second electrode ELT2 may be a cathode electrode for the light emitting unit EL. According to an embodiment, the first electrode ELT1 and the second electrode ELT2 may include a conductive material. For example, the first electrode ELT1 may include a conductive material having a reflective property, and the second electrode ELT2 may include a transparent conductive material, but the disclosure is not necessarily limited thereto. The first electrode ELT1 may be a cathode electrode for the light emitting unit EL and the second electrode ELT2 may be an anode electrode for the light emitting unit EL.

Referring to FIG. 3, the light emitting unit EL may have a multilayer thin film structure including a light generation layer (for example, a light emitting layer EML). The light emitting unit EL may include a hole injection layer HIL that injects a hole, a hole transport layer HTL that has an excellent hole transport property and suppresses a movement of an electron that is not combined in the light emitting layer EML to increase a chance of recombination of a hole and an electron, the light emitting layer EML that emits light by recombination of injected electron and hole, an electron transport layer ETL for readily transporting an electron to the light emitting layer, and an electron injection layer EIL that injects an electron. The light emitting unit EL may emit light based on an electrical signal provided from the anode electrode (for example, the first electrode ELT1) and the cathode electrode (for example, the second electrode ELT2).

According to an embodiment, referring to FIG. 4, the light emitting element LD may include a tandem structure. For example, the light emitting unit EL may include a first light emitting unit ELa, a charge generation layer CGL, and a second light emitting unit ELb.

The first light emitting unit ELa may be provided in a structure in which the hole injection layer HIL, a first hole transport layer HTLa, a first light emitting layer EMLa, and a first electron transport layer ETLa are stacked in the third direction DR3. The second light emitting unit ELb may be provided in a structure in which a second hole transport layer HTLb, a second light emitting layer EMLb, a second electron transport layer ETLa, and the electron injection layer EIL are stacked in the third direction DR3.

In an embodiment, a buffer layer (not shown) may be disposed on the first light emitting layer EMLa and the second light emitting layer EMLb. The buffer layer may include an electron transport compound.

The charge generation layer CGL may supply a charge to the first light emitting unit ELa and the second light emitting unit ELb. The charge generation layer CGL may include an n-type electron generation layer n-CGL for supplying a charge to the first light emitting unit ELa and a p-type charge generation layer p-CGL for supplying a hole to the second light emitting unit ELb. The n-type charge generation layer n-CGL may include a metal material as a dopant.

In FIG. 4, an embodiment that two light emitting units ELa and ELb of the light emitting element LD are stacked is illustrated, but the disclosure is not limited thereto. For example, in the light emitting element LD, three or four or more light emitting units may be stacked each other.

The pixel defining layer PDL may be disposed on the pixel circuit layer PCL. At least portions of the pixel defining layers PDL may be spaced apart from each other with the light emitting units EL interposed between the pixel defining layers PDL. At least a portion of the pixel defining layer PDL may be disposed on the first electrode ELT1. The pixel defining layer PDL may be disposed adjacent to the first electrode ELT1. For example, the pixel defining layer PDL may be disposed adjacent to the first electrode ELT1 in a direction in which the plane in which the base layer BSL is disposed extends. At least a portion of the pixel defining layer PDL may expose at least a portion of the first electrode ELT1. At least a portion of the pixel defining layer PDL may overlap the first electrode ELT1 in a plan view. The pixel defining layer PDL may cover an end of the first electrode ELT1.

The pixel defining layer PDL may include an inorganic material. For example, the pixel defining layer PDL may include at least one of silicon nitride (SiNₓ), silicon oxide (SiOₓ), silicon oxynitride (SiOₓN_{y}), and aluminum oxide (AlOx). However, the disclosure is not limited thereto. The pixel defining layer PDL may include an organic material. For example, the pixel defining layer PDL may include at least one of an acryl resin, an epoxy resin, a phenol resin, a polyamide resin, and a polyimide resin.

The partition walls PW may be disposed on the pixel defining layer PDL. Each of the partition walls PW may be disposed between the light emitting units EL. The partition walls PW may be disposed between or at a boundary of adjacent sub-pixels SPX1, SPX2, and SPX3 and define the first sub-pixel area SPXA1, the second sub-pixel area SPXA2, and the third sub-pixel area SPXA3.

The partition wall PW may include a multilayer stack structure. For example, the partition wall PW may include six or more layers. According to an embodiment, the partition wall PW may include a first partition wall layer PW1, a second partition wall layer PW2, a first protruding layer PL1, and a second protruding layer PL2. According to an embodiment, the first protruding layer PL1 may include a (1-1)-th protruding layer PL1_1 and a (1-2)-th protruding layer PL1_2. According to an embodiment, the second protruding layer PL2 may include a (2-1)-th protruding layer PL2_1 and a (2-2)-th protruding layer PL2_2. However, the disclosure is not necessarily limited thereto. Hereinafter, the disclosure is described based on an embodiment in which the partition wall PW has a structure having six layers including the first partition wall layer PW1, the second partition wall layer PW2, the (1-1)-th protruding layer PL1_1, the (1-2)-th protruding layer PL1_2, the (2-1)-th protruding layer PL2_1, and the (2-2)-th protruding layer PL2_2.

The first partition wall layer PW1, the first protruding layer PL1, the second partition wall layer PW2, and the second protruding layer PL2 may be stacked in a thickness direction (for example, the third direction DR3) of the base layer BSL. The first partition wall layer PW1, the second partition wall layer PW2, the (1-1)-th protruding layer PL1_1, the (1-2)-th protruding layer PL1_2, the (2-1)-th protruding layer PL2_1, and the (2-2)-th PL2_2 may be sequentially stacked in the thickness direction (for example, the third direction DR3) of the base layer BSL.

The first partition wall layer PW1 may be disposed on the pixel defining layer PDL. According to an embodiment, the first partition wall layer PW1 may be directly disposed on the pixel defining layer PDL. The first protruding layer PL1 may be disposed on the first partition wall layer PW1. According to an embodiment, the first protruding layer PL1 may be directly disposed on the first partition wall layer PW1. The second partition wall layer PW2 may be disposed on the first protruding layer PL1. According to an embodiment, the second partition wall layer PW2 may be directly disposed on the first protruding layer PL1. The second protruding layer PL2 may be disposed on the second partition wall layer PW2. According to an embodiment, the second protruding layer PL2 may be directly disposed on the second partition wall layer PW2.

In the disclosure, a width may be defined based on a direction in which the plane in which the base layer BSL is disposed extends (for example, the first direction DR1 or the second direction DR2).

According to an embodiment, each of the first partition wall layer PW1 and the second partition wall layer PW2 may have a width less than a width of the first protruding layer PL1 or the second protruding layer PL2. For example, the first protruding layer PL1 may protrude further outward than the first partition wall layer PW1 in the first direction DR1 or the second direction DR2. The second protruding layer PL2 may protrude further outward than the second partition wall layer PW2 in the first direction DR1 or the second direction DR2. In the disclosure, the outward may be a direction in which the partition wall PW faces the light emitting unit EL. The outward may be a direction in which a side surface of the partition wall PW faces. The outward may be a direction in which the first protruding layer PL1 and the second protruding layer PL2 extend.

According to an embodiment, the partition wall PW may have a structure in which a ‘T’ shaped structure is sequentially stacked in the third direction DR3. For example, the first partition wall layer PW1 and the first protruding layer PL1 may form a first tip structure with the first partition wall layer PW1 being further inward than the first protruding layer PL1, and the second partition wall layer PW2 and the second protruding layer PL2 may form a second tip structure with the second partition wall layer PW2 being further inward that the second protruding layer PL2. Accordingly, the partition wall PW may have two or more tips in the third direction DR3.

As the partition wall PW has two or more tip structures, the light emitting unit EL may contact at least a portion of a side surface of the first partition wall layer PW1 and may not contact at least a portion of a side surface of the second partition wall layer PW2. When depositing organic materials for forming the light emitting units EL, at least a portion of the light emitting units EL may be separated from each other, and each of the sub-pixels SPX1, SPX2, and SPX3 may be distinguished. For example, the light emitting unit EL may be separated into a first light emitting unit EL1, a second light emitting unit EL2, and a third light emitting unit EL3.

As the partition wall PW has two or more tip structures, the second electrode ELT2 may contact at least a portion of the side surface of the first partition wall layer PW1 and may not contact at least a portion of the side surface of the second partition wall layer PW2.

Each of the first partition wall layer PW1 and the second partition wall layer PW2 may have a quadrangular shape in a cross-sectional view. According to an embodiment, the first partition wall layer PW1 and the second partition wall layer PW2 may include an inclined side surface and may have a trapezoidal shape in a cross-sectional view. However, the disclosure is not limited thereto.

Each of the first partition wall layer PW1 and the second partition wall layer PW2 may include a conductive metal. According to an embodiment, the first partition wall layer PW1 and the second partition wall layer PW2 may include a same material. According to an embodiment, each of the first partition wall layer PW1 and the second partition wall layer PW2 may include at least one of gold (Au), silver (Ag), aluminum (Al), molybdenum (Mo), chromium (Cr), titanium (Ti), nickel (Ni), neodymium (Nd), copper (Cu), and platinum (Pt). For example, the first partition wall layer PW1 and the second partition wall layer PW2 may include molybdenum (Mo).

According to an embodiment, in case that the first partition wall layer PW1 includes molybdenum (Mo), a contact resistance with the second electrode ELT2 may be decreased. Experimentally, in a case where the first partition wall layer PW1 includes other metals, an oxide layer may be formed more quickly on a surface of the first partition wall layer PW1 than a case where the first partition wall layer PW1 includes molybdenum (Mo), and this may increase an electrical contact resistance with the second electrode ELT2. In the display device DD according to the disclosure, as the first partial wall layer PW1 includes molybdenum (Mo), in case that the second electrode ELT2 contacts the side surface of the first partition wall layer PW1, the electrical contact resistance may be decreased.

In the disclosure, in case that a thickness is defined based on the thickness direction (for example, the third direction DR3) of the base layer BSL, according to an embodiment, the first partition layer PW1 may have a thickness in a range of about 2000 Å to about 4000 Å. According to an embodiment, the second partition wall layer PW2 may have a thickness in a range of about 1000 Å to about 3000 Å. However, the disclosure is not limited thereto.

Each of the first protruding layer PL1 and the second protruding layer PL2 may include a multilayer stack structure. According to an embodiment, each of the first protruding layer PL1 and the second protruding layer PL2 may include two layers. For example, the first protruding layer PL1 may include the (1-1)-th protruding layer PL1_1 and the (1-2)-th protruding layer PL1_2 disposed on the (1-1)-th protruding layer PL1_1. For example, the second protruding layer PL2 may include the (2-1)-th protruding layer PL2_1 and the (2-2)-th protruding layer PL2_2 disposed on the (2-1)-th protruding layer PL2_1. However, the disclosure is not necessarily limited thereto. Hereinafter, the disclosure is described based on a structure in which each of the first protruding layer PL1 and the second protruding layer PL2 has two layers.

The (1-1)-th protruding layer PL1_1 may be disposed on the first partition wall layer PW1. According to an embodiment, the (1-1)-th protruding layer PL1_1 may be directly disposed on the first partition wall layer PW1. The (2-1)-th protruding layer PL2_1 may be disposed on the second partition wall layer PW2. According to an embodiment, the (2-1)-th protruding layer PL2_1 may be directly disposed on the second partition wall layer PW2.

The (1-2)-th protruding layer PL1_2 may be disposed on the (1-1)-th protruding layer PL1_1. According to an embodiment, the (1-2)-th protruding layer PL1_2 may be directly disposed on the (1-1)-th protruding layer PL1_1. The (2-2)-th protruding layer PL2_2 may be disposed on the (2-1)-th protruding layer PL2_1. According to an embodiment, the (2-2)-th protruding layer PL2_2 may be directly disposed on the (2-1)-th protruding layer PL2_1.

According to an embodiment, each of the (1-1)-th protruding layer PL1_1 and the (1-2)-th protruding layer PL1_2 may have a quadrangular shape in a cross-sectional view. According to an embodiment, the (1-1)-th protruding layer PL1_1 and the (1-2)-th protruding layer PL1_2 may include an inclined side surface. According to an embodiment, the (1-1)-th protruding layer PL1_1 and the (1-2)-th protruding layer PL1_2 may have a trapezoidal shape in a cross-sectional view. However, the disclosure is not limited thereto.

According to an embodiment, the (1-1)-th protruding layer PL1_1 and the (1-2)-th protruding layer PL1_2 may have ends that do not coincide with each other. However, the disclosure is not limited thereto, and in another embodiment, the (1-1)-th protruding layer PL1_1 and the (1-2)-th protruding layer PL1_2 may have ends that coincide with each other.

According to an embodiment, each of the (2-1)-th protruding layer PL2_1 and the (2-2)-th protruding layer PL2_2 may have a quadrangular shape in a cross-sectional view. According to an embodiment, the (2-1)-th protruding layer PL2_1 and the (2-2)-th protruding layer PL2_2 may include an inclined side surface. According to an embodiment, the (2-1)-th protruding layer PL2_1 and the (2-2)-th protruding layer PL2_2 may have a trapezoidal shape in a cross-sectional view. However, the disclosure is not limited thereto.

According to an embodiment, the (2-1)-th protruding layer PL2_1 and the (2-2)-th protruding layer PL2_2 may have ends that do not coincide with each other. However, the disclosure is not limited thereto, and in another embodiment, the (2-1)-th protruding layer PL2_1 and the (2-2)-th protruding layer PL2_2 may have ends that coincide with each other.

According to an embodiment, the (1-1)-th protruding layer PL1_1 and the (2-1)-th protruding layer PL2_1 may include an inorganic material. According to an embodiment, the (1-1)-th protruding layer PL1_1 and the (2-1)-th protruding layer PL2_1 may include a same material. According to an embodiment, the (1-1)-th protruding layer PL1_1 and the (2-1)-th protruding layer PL2_1 may include at least one of silicon nitride (SiNₓ), silicon oxide (SiOₓ), and silicon oxynitride (SiOₓN_{y}).

According to an embodiment, in case that the (1-1)-th protruding layer PL1_1 and the (2-1)-th protruding layer PL2_1 include an inorganic material, the (1-1)-th protruding layer PL1_1 and the (2-1)-th protruding layer PL2_1 may be deposited through a chemical vapor deposition (CVD) process.

According to an embodiment, the (1-1)-th protruding layer PL1_1 and the (2-1)-th protruding layer PL2_1 may have a same thickness. According to an embodiment, in case that the (1-1)-th protruding layer PL1_1 and the (2-1)-th protruding layer PL2_1 include an inorganic material, each of the (1-1)-th protruding layer PL1_1 and the (2-1)-th protruding layer PL2_1 may have a thickness in a range of about 200 Å to about 500 Å.

According to an embodiment, the (1-2)-th protruding layer PL1_2 and the (2-2)-th protruding layer PL2_2 may include at least one of titanium (Ti) and tantalum (Ta). According to an embodiment, the (1-2)-th protruding layer PL1_2 and the (2-2)-th protruding layer PL2_2 may include a same material.

According to an embodiment, the (1-2)-th protruding layer PL1_2 and the (2-2)-th protruding layer PL2_2 may have a same thickness. According to an embodiment, in case that the (1-2)-th protruding layer PL1_2 and the (2-2)-th protruding layer PL2_2 include at least one of titanium (Ti) and tantalum (Ta), the (1-2)-th protruding layer PL1_2 and the (2-2)-th protruding layer PL2_2 may have a thickness in a range of about 300 Å to about 1000 Å.

The tip structure of the partition wall PW may include a layer including at least one of titanium (Ti) and tantalum (Ta), and the display device DD according to the disclosure may have a stable partition wall PW structure. Experimentally, in case that the tip structure of the partition wall PW includes a layer including an inorganic material and having a thin thickness in a range of about 200 Å to about 500 Å, the layer including the thin inorganic material may be bent (for example, warped or broken), and thus the tip structure may be damaged.

According to the disclosure, the tip structure of the partition wall PW may be formed so that the layer including at least one of titanium (Ti) and tantalum (Ta) and the layer including the inorganic material having the thin thickness contact, and damage of the tip structure may be reduced. For example, the layer including titanium (Ti) and/or tantalum (Ta) may support the layer including the inorganic material having the thin thickness, and the layer including the thin inorganic material may be prevented from being bent (for example, warped or broken).

In the above, an embodiment in which the (1-1)-th protruding layer PL1_1 and the (2-1)-th protruding layer PL2_1 may include the inorganic material, and the (1-2)-th protruding layer PL1_2 and the (2-2)-th protruding layer PL2_2 may include at least one of titanium (Ti) and tantalum (Ta) is described, but the disclosure is not limited thereto.

According to an embodiment, the (1-1)-th protruding layer PL1_1 and the (2-1)-th protruding layer PL2_1 may include at least one of titanium (Ti) and tantalum (Ta). According to an embodiment, the (1-2)-th protruding layer PL1_2 and the (2-2)-th protruding layer PL2_2 may include an inorganic material. According to an embodiment, the (1-2)-th protruding layer PL1_2 and the (2-2)-th protruding layer PL2_2 may include at least one of silicon nitride (SiNₓ), silicon oxide (SiOₓ), and silicon oxynitride (SiOₓN_{y}).

The protective layer IL may be disposed on at least a portion of the partition wall PW and the second electrode ELT2. The protective layer IL may cover at least a portion of the partition wall PW and the second electrode ELT2. For example, the protective layer IL may contact a side surface of each of the first protruding layer PL1, the second partition wall layer PW2, and the second protruding layer PL2.

According to an embodiment, the protective layer IL may contact at least a portion of a lower surface of each of the (1-1)-th protruding layer PL1_1 and the (2-1)-th protruding layer PL2_1, and at least a portion of an upper surface of each of the (1-2)-th protruding layer PL1_2 and the (2-2)-th protruding layer PL2_2. Hereinafter, in the disclosure, an “upper” direction may be defined as the third direction DR3, and a “lower” direction may be defined as a direction of gravity, for example, a direction opposite to the third direction DR3.

In FIG. 2, the protective layer IL is illustrated as entirely covering an upper surface of the (2-2)-th protruding layer PL2_2, but the disclosure is not limited thereto. According to an embodiment, at least a portion of the protective layer IL contacting the upper surface of the (2-2)-th protruding layer PL2_2 may be removed, and thus the protective layer IL may expose at least a portion of the upper surface of the (2-2)-th protruding layer PL2_2.

The protective layer IL may include an inorganic material. For example, the protective layer IL may include at least one of silicon nitride (SiNₓ), silicon oxide (SiOₓ), silicon oxynitride (SiOₓN_{y}), and aluminum oxide (AlOx). However, the disclosure is not limited thereto, and the protective layer IL may include another insulating material.

The protective layer IL and the partition wall PW may be adjacent to each other with sufficient adhesive force. In case that the protective layer IL is not closely attached to the partition wall PW, a risk of membrane lift may occur, and providing the protective layer IL closely may be difficult.

In the display device DD according to an embodiment of the disclosure, as the partition wall PW has two or more tip structures in the third direction DR3, and the tip structure includes a layer including an inorganic material, the partition wall PW may stably contact the protective layer IL. For example, adhesive force between an inorganic layer and a metal layer may be greater than adhesive force between an inorganic layer and an inorganic layer. Accordingly, due to a material characteristic between the partition wall PW and the protective layer IL, the partition wall PW and the protective layer IL may be closely attached to each other. Accordingly, the protective layer IL may stably cover the partition wall PW to stably contact the partition wall PW, and may reduce a risk that an external impurity (for example, moisture) permeates into the display device DD.

Hereinafter, with reference to FIG. 5, an electrical connection structure between the light emitting element LD and the partition wall PW is described. FIG. 5 is a schematic block diagram illustrating an electrical connection structure for a light emitting element according to an embodiment. For example, FIG. 5 may illustrate an electrical connection structure including the pixel circuit PXC corresponding to each sub-pixel SPX.

Referring to FIG. 5, the sub-pixel SPX may include the pixel circuit PXC configured to drive the light emitting element LD.

The pixel circuit PXC may include one or more circuit elements. For example, the pixel circuit PXC may include transistors and a storage capacitor. For example, the pixel circuit PXC may include a driving transistor, a switching transistor, and a storage capacitor. However, the disclosure is not necessarily limited thereto.

The pixel circuit PXC may be electrically connected to a scan line SL and a data line DL. The scan line SL may supply a scan signal to the pixel circuit PXC, and according to an embodiment, may be electrically connected to a gate electrode of the switching transistor of the pixel circuit PXC. The light emitting element LD may be configured to emit light corresponding to a data signal provided from the data line DL.

The pixel circuit PXC may be electrically connected to a first power line PLL1 and a second power line PLL2. For example, the first electrode ELT1 of the light emitting element LD may be electrically connected to the pixel circuit PXC and the first power line PLL1, and the second electrode ELT2 of the light emitting element LD may be electrically connected to the second power line PLL2. According to an embodiment, the second power line PLL2 may be formed in the pixel circuit layer PCL in the display area DA. In another embodiment, the second power line PLL2 may be disposed in the non-display area NDA. Accordingly, the second power line PLL2 may be configured to supply second power to the light emitting element LD.

Power of the first power line PLL1 and power of the second power line PLL2 may have different potentials. For example, the power of the first power line PLL1 may be high-potential pixel power receiving power from a first voltage potential VDD, and the power of the second power line PLL2 may be low-potential pixel power receiving power from second voltage potential VSS. A potential difference between the power of the first power line PLL1 and the power of the second power line PLL2 may be set to be equal to or greater than a threshold voltage of the light emitting elements LD.

The first power line PLL1 may be electrically connected to the pixel circuit PXC (for example, the driving transistor). The second power line PLL2 may be electrically connected to the cathode electrode (for example, the second electrode ELT2) of the light emitting element LD.

According to an embodiment, the second power line PLL2 may be electrically connected to the second electrode ELT2 through the partition wall PW. For example, the partition wall PW may electrically connect the second electrode ELT2 and the second power line PLL2.

Each light emitting element LD may be connected in a forward direction between the first power line PLL1 and the second power line PLL2 to form each effective light source. These effective light sources may be gathered together to form the light emitting elements LD of the sub-pixel SPX.

The light emitting elements LD may emit light with a luminance corresponding to a driving current supplied through the pixel circuit PXC. During each frame period, the pixel circuit PXC may supply the driving current corresponding to the data signal to the light emitting element LD. The light emitting element LD may emit light with a luminance corresponding to a current flowing in the light emitting element LD.

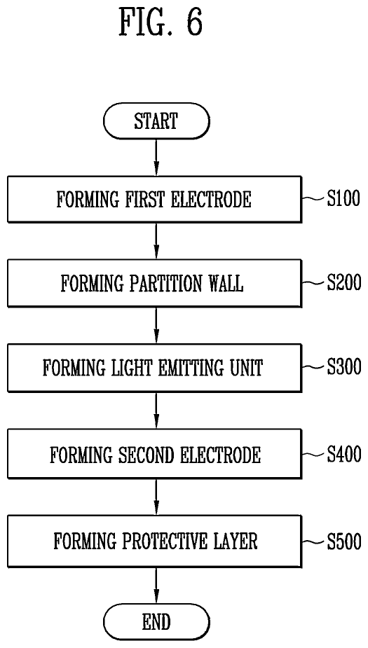

Hereinafter, with reference to FIGS. 6 to 13, a method of manufacturing the display device DD is described.

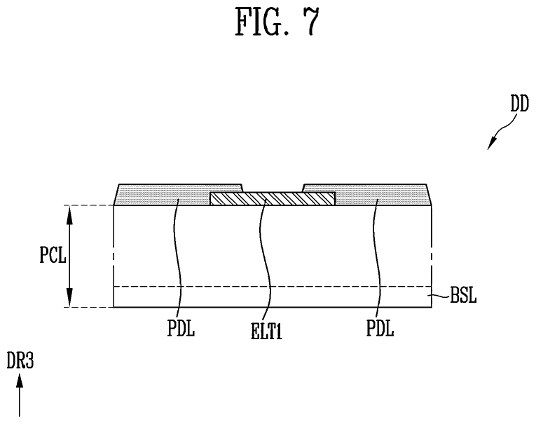

FIG. 6 is a schematic flowchart illustrating a method of manufacturing a display device according to an embodiment. FIGS. 7 to 13 are schematic cross-sectional views for each process step illustrating a method of manufacturing a display device according to an embodiment.

Referring to FIG. 6, the method of manufacturing the display device DD may include forming a first electrode (S100), forming a partition wall (S200), forming a light emitting unit (S300), forming a second electrode (S400), and forming a protective layer (S500).

Referring to FIG. 7, in forming the first electrode (S100), the first electrodes ELT1 may be patterned on the base layer BSL (or the pixel circuit layer PCL).

Before patterning the first electrode ELT1, the pixel circuit layer PCL including the pixel circuit PXC for driving the light emitting elements LD may be formed (for example, patterned) on the base layer BSL. The pixel circuit layer PCL may be formed (for example, patterned) to include conductive layers and insulating layers disposed between the conductive layers.

According to an embodiment, configurations disposed on the base layer BSL may be formed (for example, patterned) through a general patterning process (for example, a photolithography process or the like) using a mask.

In forming the first electrode (S100), the first electrode ELT1 may be formed (for example, patterned) on the pixel circuit layer PCL (or the base layer BSL). According to an embodiment, the first electrode ELT1 may be deposited on the pixel circuit layer PCL and may be etched to expose at least a portion of the pixel circuit layer PCL.

In the disclosure, unless otherwise specified regarding a deposition process used to form (for example, pattern) a configuration of the display device DD, as a process for depositing the configuration of the display device DD, one or more of a chemical vapor deposition (CVD) process and an atomic layer deposition (ALD) process may be used. In the disclosure, unless otherwise specified regarding an etching process used to form (for example, pattern) the configuration of the display device DD, as the etching process, one or more of wet etching and dry etching may be used. However, the disclosure is not limited to a specific example.

Although not shown in the drawing, according to an embodiment, after the first electrode ELT1 is formed (for example, patterned), the first electrode ELT1 may be electrically connected to the driving transistor through a hole passing through the protective layer in the pixel circuit layer PCL.

According to an embodiment, after the first electrode ELT1 is formed, a process of patterning (or forming) the pixel defining layer PDL may be further performed. According to an embodiment, the pixel defining layer PDL may be deposited on the first electrode ELT1 and etched to expose at least a portion of the first electrode ELT1.

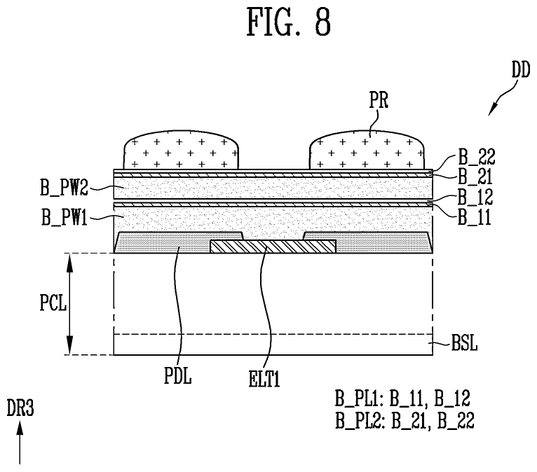

Referring to FIG. 8, in forming the partition wall (S200), a first base partition layer B_PW1, a first base protruding layer B_PL1, a second base partition layer B_PW2, and a second base protruding layer B_PL2 may be deposited on the first electrode ELT1 (or the base layer BSL).

In the disclosure, the first base partition wall layer B_PW1, the first base protruding layer B_PL1, the second base partition wall layer B_PW2, and the second base protruding layer B_PL2 may be layers deposited on the first electrode ELT1 (or the base layer BSL) before an etching process is performed, as layers for forming the first partition wall layer PW1, the first protruding layer PL1, the second partition wall layer PW2, and the second protruding layer PL2, respectively.

In depositing the first base partition wall layer B_PW1, the first base partition wall layer B_PW1 may be deposited on the first electrode ELT1. According to an embodiment, the first base partition wall layer B_PW1 may be directly deposited on the first electrode ELT1.

According to an embodiment, the first base partition wall layer B_PW1 may include a conductive metal. According to an embodiment, the first base partition wall layer B_PW1 may include at least one of gold (Au), silver (Ag), aluminum (Al), molybdenum (Mo), chromium (Cr), titanium (Ti), nickel (Ni), neodymium (Nd), copper (Cu), and platinum (Pt). For example, the first base partition wall layer B_PW1 may include molybdenum (Mo).

According to an embodiment, the first base partition wall layer B_PW1 may be deposited through a sputtering process.

According to an embodiment, the first base partition wall layer B_PW1 may be deposited to have a thickness in a range of about 2000 Å to about 4000 Å.

After the first base partition wall layer B_PW1 is deposited, a process of depositing the first base protruding layer B_PL1 may be performed. Depositing the first base protruding layer B_PL1 may include depositing a (1-1)-th base protruding layer B_11 and depositing a (1-2)-th base protruding layer B_12.

The first base protruding layer B_PL1 may be deposited on the first base partition wall layer B_PW1. According to an embodiment, the first base protruding layer B_PL1 may be directly deposited on the first base partition wall layer B_PW1.

The (1-1)-th base protruding layer B_11 may be deposited on the first base partition wall layer B_PW1. According to an embodiment, the (1-1)-th base protruding layer B_11 may be directly deposited on the first base partition wall layer B_PW1.

The (1-2)-th base protruding layer B_12 may be deposited on the (1-1)-th base protruding layer B_11. According to an embodiment, the (1-2)-th base protruding layer B_12 may be directly deposited on the (1-1)-th base protruding layer B_11.

According to an embodiment, the (1-1)-th base protruding layer B_11 may include an inorganic material, and the (1-2)-th base protruding layer B_12 may include at least one of titanium (Ti) and tantalum (Ta). According to an embodiment, the (1-1)-th base protruding layer B_11 may include at least one of silicon nitride (SiNₓ), silicon oxide (SiOₓ), and silicon oxynitride (SiOₓN_{y}). However, the disclosure is not limited thereto. According to an embodiment, the (1-2)-th base protruding layer B_12 may include a metal having an etch selectivity with respect to the first partition wall layer PW1 during an etching process is performed.

According to an embodiment, the (1-1)-th base protruding layer B_11 may include at least one of titanium (Ti) and tantalum (Ta), and the (1-2)-th base protruding layer B_12 may include an inorganic material. According to an embodiment, the (1-2)-th base protruding layer B_12 may include at least one of silicon nitride (SiNₓ), silicon oxide (SiOₓ), and silicon oxynitride (SiOₓN_{y}). However, the disclosure is not limited thereto. According to an embodiment, the (1-1)-th base protruding layer B_11 may include a metal having an etch selectivity with respect to the first partition wall layer PW1 during an etching process is performed.

According to an embodiment, in case that the (1-1)-th base protruding layer B_11 includes an inorganic material, the (1-1)-th base protruding layer B_11 may be deposited through a CVD process. According to an embodiment, in case that the (1-2)-th base protruding layer B_12 includes at least one of titanium (Ti) and tantalum (Ta), the (1-2)-th base protruding layer B_12 may be deposited through a sputtering process.

According to an embodiment, in case that the (1-1)-th base protruding layer B_11 includes at least one of titanium (Ti) and tantalum (Ta), the (1-1)-th base protruding layer B_11 may be deposited through a sputtering process. According to an embodiment, in case that the (1-2)-th base protruding layer B_12 includes an inorganic material, the (1-2)-th base protruding layer B_12 may be deposited through a CVD process.

According to an embodiment, in case that the (1-1)-th base protruding layer B_11 includes an inorganic material, the (1-1)-th base protruding layer B_11 may be deposited to have a thickness in a range of about 200 Å to about 500 Å. According to an embodiment, in case that the (1-2)-th base protruding layer B_12 includes at least one of titanium (Ti) and tantalum (Ta), the (1-2)-th base protruding layer B_12 may be deposited to have a thickness in a range of about 300 Å to about 1000 Å.

According to an embodiment, in case that the (1-1)-th base protruding layer B_11 includes at least one of titanium (Ti) and tantalum (Ta), the (1-1)-th base protruding layer B_11 may be deposited to have a thickness in a range of about 300 Å to about 1000 Å. According to an embodiment, in case that the (1-2)-th base protruding layer B_12 includes an inorganic material, the (1-2)-th base protruding layer B_12 may be deposited to have a thickness in a range of about 200 Å to about 500 Å.

After the first base protruding layer B_PL1 is deposited, a process of depositing the second base partition wall layer B_PW2 may be performed. In depositing the second base partition wall layer B_PW2, the second base partition wall layer B_PW2 may be deposited on the first base protruding layer B_PL1. According to an embodiment, the second base partition wall layer B_PW2 may be directly deposited on the first base protruding layer B_PL1.

According to an embodiment, the second base partition wall layer B_PW2 may include a conductive metal. According to an embodiment, the second base partition wall layer B_PW2 and the first base partition wall layer B_PW1 may include a same material. According to an embodiment, the second base partition wall layer B_PW2 may include molybdenum (Mo).

According to an embodiment, the second base partition wall layer B_PW2 may be deposited through a sputtering process.

According to an embodiment, the second base partition wall layer B_PW2 may be deposited to have a thickness in a range of about 1000 Å to about 3000 Å.

After the second base partition wall layer B_PW2 is deposited, a process of depositing the second base protruding layer B_PL2 may be performed. Depositing the second base protruding layer B_PL2 may include depositing the (2-1)-th base protruding layer B_21 and depositing the (2-2)-th base protruding layer B_22.

The second base protruding layer B_PL2 may be deposited on the second base partition wall layer B_PW2. According to an embodiment, the second base protruding layer B_PL2 may be directly deposited on the second base partition wall layer B_PW2.

The (2-1)-th base protruding layer B_21 may be deposited on the second base partition wall layer B_PW2. According to an embodiment, the (2-1)-th base protruding layer B_21 may be directly deposited on the second base partition wall layer B_PW2.

The (2-2)-th base protruding layer B_22 may be deposited on the (2-1)-th base protruding layer B_21. According to an embodiment, the (2-2)-th base protruding layer B_22 may be directly deposited on the (2-1)-th base protruding layer B_21.

According to an embodiment, the (2-1)-th base protruding layer B_21 may include an inorganic material, and the (2-2)-th base protruding layer B_22 may include at least one of titanium (Ti) and tantalum (Ta). According to an embodiment, the (2-1)-th base protruding layer B_21 may include at least one of silicon nitride (SiNₓ), silicon oxide (SiOₓ), and silicon oxynitride (SiOₓN_{y}). However, the disclosure is not limited thereto. According to an embodiment, the (2-2)-th base protruding layer B_22 may include a metal having an etch selectivity with respect to the second partition wall layer PW2 during an etching process is performed.

According to an embodiment, the (2-1)-th base protruding layer B_21 may include at least one of titanium (Ti) and tantalum (Ta), and the (2-2)-th base protruding layer B_22 may include an inorganic material. According to an embodiment, the (2-2)-th base protruding layer B_22 may include at least one of silicon nitride (SiNₓ), silicon oxide (SiOₓ), and silicon oxynitride (SiOₓN_{y}). However, the disclosure is not limited thereto. According to an embodiment, the (2-1)-th base protruding layer B_21 may include a metal having an etch selectivity with respect to the second partition layer PW2 during an etching process is performed.

According to an embodiment, in case that the (2-1)-th base protruding layer B_21 includes an inorganic material, the (2-1)-th base protruding layer B_21 may be deposited through a CVD process. According to an embodiment, in case that the (2-2)-th base protruding layer B_22 includes at least one of titanium (Ti) and tantalum (Ta), the (2-2)-th base protruding layer B_22 may be deposited through a sputtering process.

According to an embodiment, in case that the (2-1)-th base protruding layer B_21 includes at least one of titanium (Ti) and tantalum (Ta), the (2-1)-th base protruding layer B_21 may be deposited through a sputtering process. According to an embodiment, in case that the (2-2)-th base protruding layer B_22 includes an inorganic material, the (2-2)-th base protruding layer B_22 may be deposited through a CVD process.

The (2-1)-th base protruding layer B_21 and the (1-1)-th base protruding layer B_11 may be deposited to have a same thickness. According to an embodiment, in case that the (2-1)-th base protruding layer B_21 includes an inorganic material, the (2-1)-th base protruding layer B_21 may be deposited to have a thickness in a range of about 200 Å to about 500 Å. The (2-2)-th base protruding layer B_22 and the (1-2)-th base protruding layer B_12 may be deposited to have a same thickness. According to an embodiment, in case that the (2-2)-th base protruding layer B_22 includes at least one of titanium (Ti) and tantalum (Ta), the (2-2)-th base protruding layer B_22 may be deposited to have a thickness in a range of about 300 Å to about 1000 Å.

According to an embodiment, in case that the (2-1)-th base protruding layer B_21 includes at least one of titanium (Ti) and tantalum (Ta), the (2-1)-th base protruding layer B_21 may be deposited to have a thickness in a range of about 300 Å to about 1000 Å. According to an embodiment, in case that the (2-2)-th base protruding layer B_22 includes an inorganic material, the (2-2)-th base protruding layer B_22 may be deposited to have a thickness in a range of about 200 Å to about 500 Å.

After the first base partition wall layer B_PW1, the first base protruding layer B_PL1, the second base partition wall layer B_PW2, and the second base protruding layer B_PL2 are deposited, a photoresist PR may be disposed on the second base protruding layer B_PL2. For example, the photoresist PR may be directly disposed on the (2-2)-th base protruding layer B_22.

The photoresist PR may not overlap at least a portion of the first electrode ELT1 in a plan view. The photoresist PR may overlap the pixel defining layer PDL in a plan view.

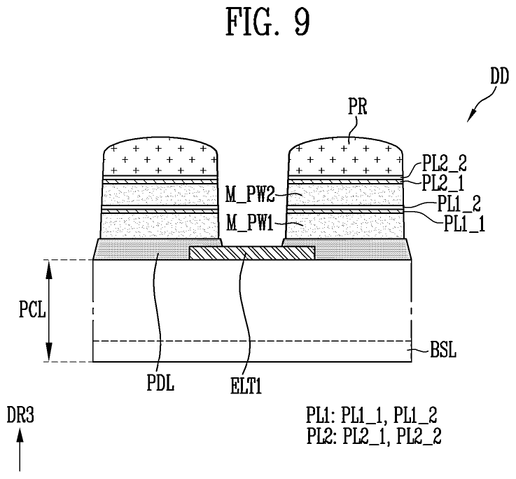

Referring to FIG. 9, the first base partition wall layer B_PW1, the first base protruding layer B_PL1, the second base partition wall layer B_PW2, and the second base protruding layer B_PL2 may be etched. The first base partition wall layer B_PW1, the first base protruding layer B_PL1, the second base partition wall layer B_PW2, and the second base protruding layer B_PL2 may be dry etched in batches. In the display device DD according to the disclosure, as the first base partition wall layer B_PW1, the first base protruding layer B_PL1, the second base partition wall layer B_PW2, and the second base protruding layer B_PL2 are deposited and etched in batches, an additional mask other than the photoresist PR may not be required, and a process may be simplified.

According to an embodiment, the first base partition wall layer B_PW1, the first base protruding layer B_PL1, the second base partition wall layer B_PW2, and the second base protruding layer B_PL2 that do not overlap the photoresist PR may be etched in a plan view. Etching the first base partition wall layer B_PW1, the first base protruding layer B_PL1, the second base partition wall layer B_PW2, and the second base protruding layer B_PL2 may include forming a first intermediate partition wall layer M_PW1, the first protruding layer PL1, a second intermediate partition wall layer M_PW2, and the second protruding layer PL2 by etching the first base partition wall layer B_PW1, the first base protruding layer B_PL1, the second base partition wall layer B_PW2, and the second base protruding layer B_PL2, respectively.

In the disclosure, the first intermediate partition wall layer M_PW1 and the second intermediate partition wall layer M_PW2 may be layers formed by the first base partition wall layer B_PW1 and the second base partition wall layer B_PW2 through a single etching process.

The first base partition wall layer B_PW1, the first base protruding layer B_PL1, the second base partition wall layer B_PW2, and the second base protruding layer B_PL2 may be etched to have a quadrangular shape in a cross-sectional view. According to an embodiment, the first intermediate partition wall layer M_PW1, the first protruding layer PL1, the second intermediate partition wall layer M_PW2, and the second protruding layer PL2 may include an inclined side surface and may have a trapezoidal shape in a cross-sectional view. However, the disclosure is not limited thereto.

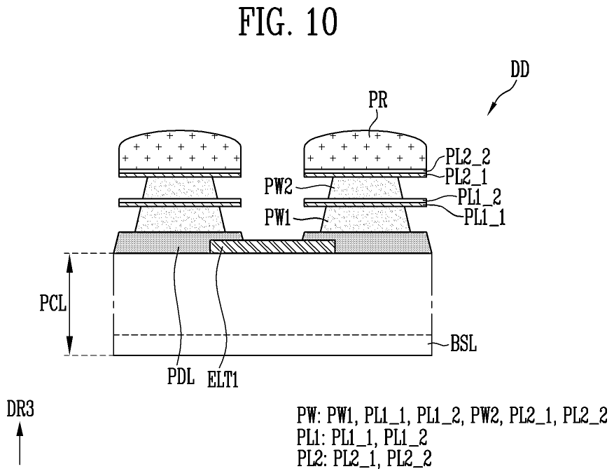

Referring to FIG. 10, etching the first base partition wall layer B_PW1, the first base protruding layer B_PL1, the second base partition wall layer B_PW2, and the second base protruding layer B_PL2 may include further etching the first intermediate partition wall layer M_PW1 and the second intermediate partition wall layer M_PW2. The first intermediate partition wall layer M_PW1 and the second intermediate partition wall layer M_PW2 may be etched to form the first partition wall layer PW1 and the second partition wall layer PW2, respectively. The first intermediate partition wall layer M_PW1 and the second intermediate partition wall layer M_PW2 may be dry etched.

According to an embodiment, in case that the first base partition wall layer B_PW1 and the second base partition wall layer B_PW2 include molybdenum (Mo), the first base partition wall layer B_PW1 and the second base partition wall layer B_PW2 may be readily isotropically dry etched.

The first intermediate partition wall layer M_PW1 and the second intermediate partition wall layer M_PW2 may be further etched to go inward than the first protruding layer PL1 and the second protruding layer PL2. The first partition wall layer PW1 may have an end that does not coincide with the first protruding layer PL1 in a plan view. The end of the first partition wall layer PW1 and the end of the first protruding layer PL1 may not overlap in a plan view. The second partition wall layer PW2 may have an end that does not coincide with the second protruding layer PL2 in a plan view. The end of the second partition layer PW2 and the end of the second protruding layer PL2 may not overlap in a plan view.

After the first intermediate partition wall layer M_PW1 and the second intermediate partition wall layer M_PW2 are further etched to form the first partition wall layer PW1 and the second partition wall layer PW2, the photoresist PR may be removed.

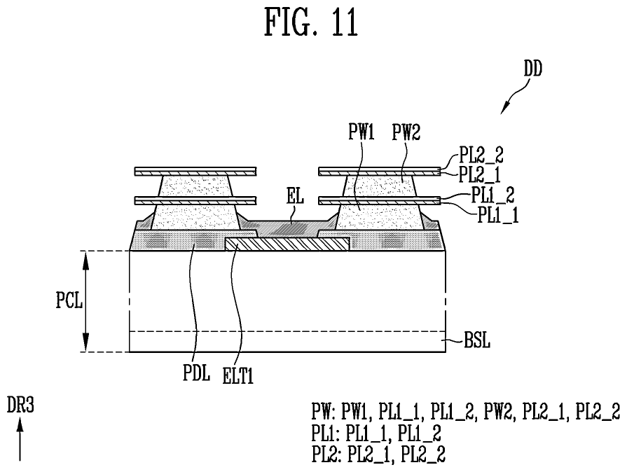

Referring to FIG. 11, in forming the light emitting unit (S400), the light emitting unit EL may be formed on the first electrode ELT1. The light emitting units EL may be formed (for example, patterned) to be disposed adjacent to the partition wall PW in a direction of a plane in which the base layer BSL is disposed. The light emitting unit EL may be deposited to contact at least a portion of the side surface of the first partition wall layer PW1. The light emitting unit EL may expose a remaining portion of the side surface of the first partition wall layer PW1. According to an embodiment, the light emitting unit EL may not contact the second partition wall layer PW2.

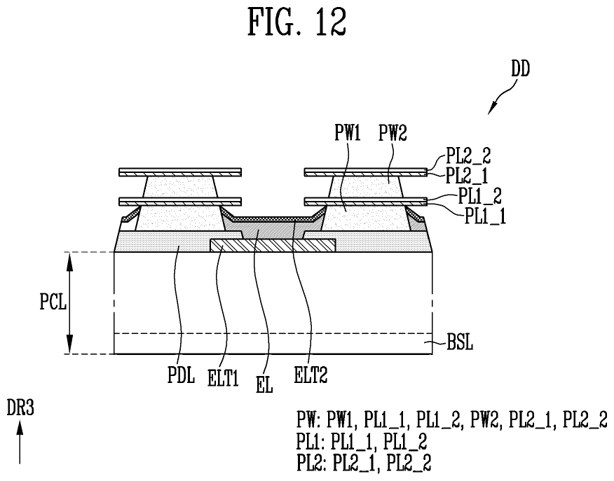

Referring to FIG. 12, in forming the second electrode (S500), the second electrode ELT2 may be formed on the light emitting unit EL. The second electrode ELT2 may contact a remaining portion of the side surface of the first partition wall layer PW1. According to an embodiment, the second electrode ELT2 may not contact the second partition wall layer PW2.

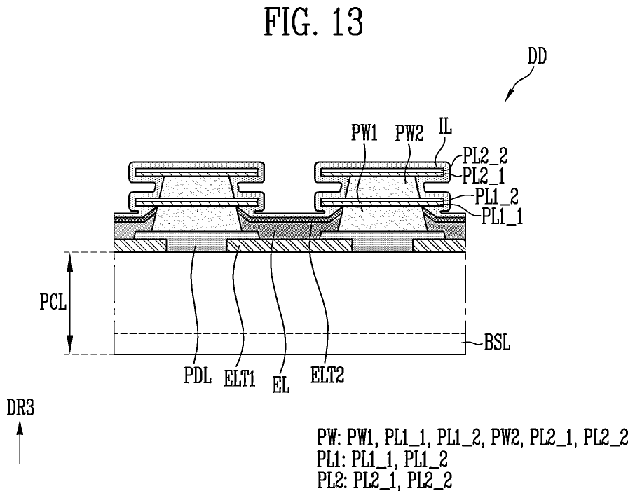

Referring to FIG. 13, in forming the protective layer IL (S600), the protective layer IL may be formed on at least a portion of the partition wall PW and the second electrode ELT2. The protective layer IL may be deposited to cover at least a portion of the partition wall PW and the second electrode ELT2.

According to an embodiment, the protective layer IL may contact a side surface of the second partition wall layer PW2, at least a portion of a lower surface of each of the (1-1)-th protruding layer PL1_1 and the (2-1)-th protruding layer PL2_1, and at least a portion of an upper surface of each of the (1-2)-th protruding layer PL1_2 and the (2-2)-th protruding layer PL2_2.

The protective layer IL may include an inorganic material. For example, the protective layer IL may include at least one of silicon nitride (SiNₓ), silicon oxide (SiOₓ), silicon oxynitride (SiOₓN_{y}), and aluminum oxide (AlOx). However, the disclosure is not limited thereto, and the protective layer IL may include another insulating material.

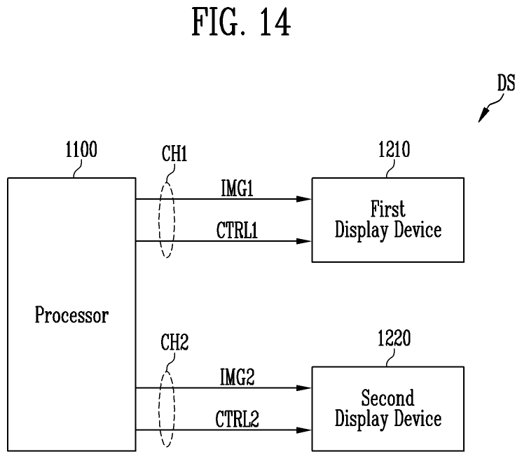

Hereinafter, a display system DS to which the display device DD may be applied is described with reference to FIGS. 14 to 16.

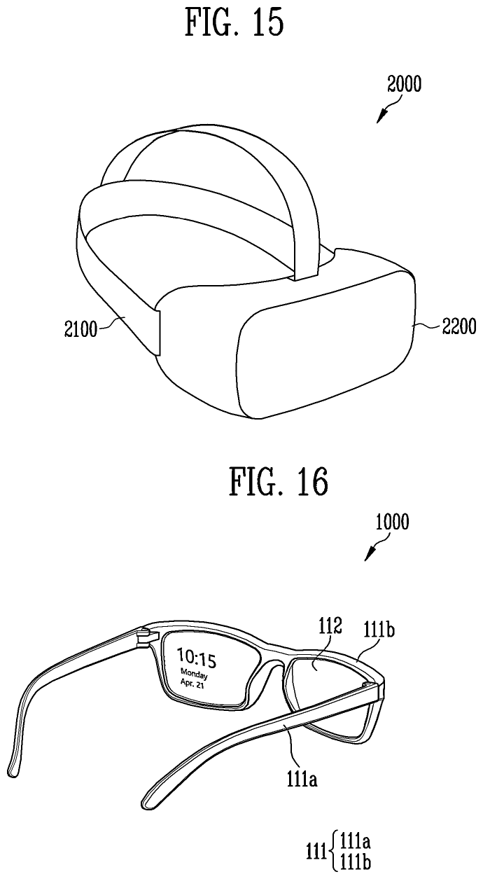

FIG. 14 is a schematic block diagram of a display system according to an embodiment. FIGS. 15 and 16 are schematic perspective views illustrating an application example of the display system of FIG. 14.

Referring to FIG. 14, the display system DS may include a processor 1100 and one or more display devices 1210 and 1220.

The processor 1100 may perform various tasks and calculations. In embodiments, the processor 1100 may include an application processor, a graphic processor, a microprocessor, a central processing unit (CPU), and the like. The processor 1100 may be connected to other components of the display system DS through a bus system to control the other components of the display system DS.

In FIG. 14, the display system DS is shown to include the first and second display devices 1210 and 1220. The processor 1100 may be connected to the first display device 1210 through a first channel CH1 and may be connected to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may be configured similarly to the display device DD described with reference to FIG. 1.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may be configured similarly to the display device DD described with reference to FIG. 1.

The display system DS may include a computing system providing an image display function, such as a portable computer, a mobile phone, a smart phone, a tablet personal computer (PC), a smart watch, a watch phone, a portable multimedia player (PMP), a navigation system, and an ultra mobile personal computer (UMPC). The display system DS may include at least one of a head mounted display (HMD) device, a virtual reality (VR) device, a mixed reality (MR) device, and an augmented reality (AR) device.

Referring to FIG. 15, the display system DS of FIG. 14 may be applied to a head mounted display device 2000. The head mounted display device 2000 may be a wearable electronic device that may be worn on a user's head.

The head mounted display device 2000 may include a head mount band 2100 and a display device receiving case 2200. The head mount band 2100 may be connected to the display device receiving case 2200. The head mount band 2100 may include a horizontal band and/or a vertical band for fixing the head mounted display device 2000 to the user's head. The horizontal band may be configured to surround a side portion of the user's head, and the vertical band may be configured to surround an upper portion of the user's head. However, the disclosure is not limited thereto. For example, the head mount band 2100 may be implemented in a glasses frame form, a helmet form, or the like.

The display device receiving case 2200 may receive the first and second display devices 1210 and 1220 of FIG. 14. The display device receiving case 2200 may further receive the processor 1100 of FIG. 14.

Referring to FIG. 16, the display system DS of FIG. 14 may be applied to a smart glass 1000.

The smart glass 1000 may include a frame 111 and a lens unit 112. The smart glass 1000 may be a wearable electronic device that may be worn on a user's face, and may have a structure in which a portion of the frame 111 is foldable. For example, the smart glass 1000 may be a wearable device for augmented reality. However, the disclosure is not limited thereto.

The frame 111 may include a housing 111b supporting the lens unit 112 and a leg unit 111a for being worn by a user. The leg unit 111a may be connected to the housing 111b by a foldable hinge.

A battery, a touch pad, a microphone, a camera, and/or the like may be embedded in the frame 111. A projector for outputting light, a processor for controlling a light signal, and/or the like may be embedded in the frame 111.

The lens unit 112 may be an optical member that transmits light or reflects light. The lens unit 112 may include glass, transparent synthetic resin, and/or the like.

The display device DD may be applied to the lens unit 112 of the smart glass 1000. For example, the user may recognize an image displayed by an optical signal transmitted from the projector of the frame 111 through the lens unit 112. For example, the user may recognize information such as time and date displayed on the lens unit 112.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a partition wall disposed on a base layer; and
a light emitting unit disposed adjacent to the partition wall, wherein
the partition wall comprises:
a first partition wall layer;
a second partition wall layer disposed on the first partition wall layer;
a first protruding layer disposed between the first partition wall layer and the second partition wall layer; and
a second protruding layer disposed on the second partition layer,
the first protruding layer protrudes over the first partition wall layer, and
the second protruding layer protrudes over the second partition wall layer.

2. The display device according to claim 1, wherein the first partition wall layer and the second partition wall layer include a conductive metal.

3. The display device according to claim 2, wherein the first partition wall layer and the second partition wall layer include molybdenum (Mo).

4. The display device according to claim 1, wherein
the first partition wall layer has a thickness in a range of about 2000 Å to about 4000 Å, and
the second partition wall layer has a thickness in a range of about 1000 Å to about 3000 Å.

5. The display device according to claim 1, wherein the first partition wall layer and the second partition wall layer have an inclined side surface.

6. The display device according to claim 1, wherein
the first protruding layer comprises:
a first-first protruding layer disposed on the first partition wall layer; and
a first-second protruding layer disposed on the first-first protruding layer, and
the second protruding layer comprises:
a second-first protruding layer disposed on the second partition wall layer; and
a second-second protruding layer disposed on the second-first protruding layer.

7. The display device according to claim 6, wherein
the first-first protruding layer and the second-first protruding layer include at least one of silicon nitride (SiNₓ), silicon oxide (SiOₓ), and silicon oxynitride (SiOₓN_{y}), and
the first-second protruding layer and the second-second protruding layer include at least one of titanium (Ti) and tantalum (Ta).

8. The display device according to claim 6, wherein
the first-second protruding layer and the second-second protruding layer include at least one of silicon nitride (SiNₓ), silicon oxide (SiOₓ), and silicon oxynitride (SiOₓN_{y}), and
the first-first protruding layer and the second-first protruding layer include at least one of titanium (Ti) and tantalum (Ta).

9. The display device according to claim 7, wherein
the first-first protruding layer and the second-first protruding layer have a thickness in a range of about 200 Å to about 500 Å, and
the first-second protruding layer and the second-second protruding layer have a thickness in a range of about 300 Å to about 1000 Å.

10. The display device according to claim 8, wherein
the first-second protruding layer and the second-second protruding layer have a thickness in a range of about 200 Å to about 500 Å, and
the first-first protruding layer and the second-first protruding layer have a thickness in a range of about 300 Å to about 1000 Å.

11. The display device according to claim 6, further comprising:
a protective layer covering at least a portion of the partition wall,
wherein the protective layer contacts a side surface of the second partition wall layer, at least a portion of a lower surface of each of the first-first protruding layer and the second-first protruding layer, and an upper surface of each of the first-second protruding layer and the second-second protruding layer.

12. The display device according to claim 6, further comprising:
a first electrode and a second electrode disposed on the base layer, wherein
the light emitting unit is disposed on the first electrode,
the second electrode is disposed on the light emitting unit, and
the second electrode contacts a side surface of the first partition wall layer and does not contact a side surface of the second partition wall layer.

13. A method of manufacturing a display device, the method comprising:
forming a partition wall on a base layer; and
forming a light emitting unit adjacent to the partition wall, wherein
the forming of the partition wall on the base layer comprises:
depositing a first base partition wall layer, a first base protruding layer, a second base partition wall layer, and a second base protruding layer on the base layer; and
etching the first base partition wall layer, the first base protruding layer, the second base partition wall layer, and the second base protruding layer,
the etching of the first base partition wall layer, the first base protruding layer, the second base partition wall layer, and the second base protruding layer comprises:
forming a first partition wall layer;
forming a second partition wall layer on the first partition wall layer;
forming a first protruding layer between the first partition wall layer and the second partition wall layer; and
forming a second protruding layer on the second partition wall layer,
the first protruding layer protrudes over the first partition wall layer, and
the second protruding layer protrudes over the second partition wall layer.

14. The method according to claim 13, wherein the first partition wall layer and the second partition wall layer include molybdenum (Mo).

15. The method according to claim 13, wherein the first base partition wall layer and the second base partition wall layer are deposited through a sputtering process.

16. The method according to claim 13, wherein
the first protruding layer comprises:
a first-first protruding layer disposed on the first partition wall layer; and
a first-second protruding layer disposed on the first-first protruding layer, and
the second protruding layer comprises:
a second-first protruding layer disposed on the second partition wall layer; and
a second-second protruding layer disposed on the second-first protruding layer.

17. The method according to claim 16, wherein
the first-first protruding layer and the second-first protruding layer include at least one of silicon nitride (SiNₓ), silicon oxide (SiOₓ), and silicon oxynitride (SiOₓN_{y}), and are deposited through a chemical vapor deposition (CVD) process, and
the first-second protruding layer and the second-second protruding layer include at least one of titanium (Ti) and tantalum (Ta).

18. The method according to claim 16, wherein
the first-second protruding layer and the second-second protruding layer include at least one of silicon nitride (SiNₓ), silicon oxide (SiOₓ), and silicon oxynitride (SiOₓN_{y}), and are deposited through a chemical vapor deposition (CVD) process, and
the first-first protruding layer and the second-first protruding layer include at least one of titanium (Ti) and tantalum (Ta).

19. The method according to claim 13, wherein in the etching of the first base partition wall layer, the first base protruding layer, the second base partition wall layer, and the second base protruding layer,
the first base partition wall layer, the first base protruding layer, the second base partition wall layer, and the second base protruding layer are dry etched in batches,
the first base partition wall layer forms a first intermediate partition wall layer, and
the second base partition wall layer forms a second intermediate partition wall layer.

20. The method according to claim 19, wherein the first intermediate partition wall layer and the second intermediate partition wall layer are further dry etched to form the first partition wall layer and the second partition wall layer, respectively.
